(19) United States
(12) Patent Application Publication
(10) Pub. No.: US 2024/0162157 A1
(43) Pub. Date: May 16, 2024

(54) BUMPLESS HYBRID ORGANIC GLASS INTERPOSER

(71) Applicant: Intel Corporation, Santa Clara, CA (US)

(72) Inventors: Jeremy D. Ecton, Gilbert, AZ (US); Brandon Christian Marin, Gilbert, AZ (US); Aleksandar Aleksov, Chandler, AZ (US); Srinivas V. Pietambaram, Chandler, AZ (US); Haobo Chen, Chandler, AZ (US)

(73) Assignee: Intel Corporation, Santa Clara, CA (US)

(21) Appl. No.: 17/988,051

(22) Filed: Nov. 16, 2022

(51) Int. Cl. H01L 23/538; H01L 21/48; H01L 23/15; H01L 23/498

(52) U.S. Cl. CPC H01L 23/5386; H01L 21/4853; H01L 21/4857; H01L 21/486; H01L 23/15; H01L 23/49816; H01L 23/49822; H01L 23/49833; H01L 23/49838; H01L 23/5385; H01L 25/0655

(57) ABSTRACT

A bumpless hybrid organic glass interposer. One or more high density pattern (HDP) routing layers are placed on a functional, thin, carrier, separate from the intended organic substrate patch or package. The HDP layer(s) is/are then attached to the substrate package. The interposers achieve electrical connections between the HDP layer and underlying routing layer of the substrate package by utilizing a self-align dry etch process through landing pads connected to the HDP routing.

### BACKGROUND

Die partitioning is a sophisticated packaging approach that enables high performance with miniaturization of form factor and increased levels of integration. However, die partitioning introduces technical challenges, such as, the scaling and routing required to achieve fine die-to-die interconnections. A variety of interconnection architectures and approaches have been proposed and are being actively investigated to meet high performance and miniaturization demands.

### BRIEF DESCRIPTION OF THE DRAWINGS

FIG. 1 illustrates an example multi-die assembly that implements interposers, in accordance with various embodiments.

FIG. 2 is a simplified cross-sectional illustration of a substrate patch, in accordance with various embodiments.

FIG. 3 provides a side view and top view of a stitching material with HDP, in accordance with various embodiments.

FIG. 4 is a non-limiting example of an interposer based on FIG. 3 attached to the substrate patch of FIG. 2.

FIGS. 5-8 are simplified illustrations depicting various stages of development of an interposer with a single layer HDP combined with the substrate patch from FIG. 2.

FIGS. 9-10 are simplified illustrations depicting various stages of development of an interposer with a multiple layers of HDP combined with the substrate patch from FIG. 2.

FIGS. 11-12 illustrate an example method for manufacturing and implementing an interposer, in accordance with various embodiments.

FIG. 13 is a top view of a wafer and dies that may be included in a microelectronic assembly, in accordance with any of the embodiments disclosed herein.

FIG. 14 s a simplified cross-sectional side view showing an implementation of an integrated circuit on a die that may be included in various embodiments, in accordance with any of the embodiments disclosed herein.

FIG. 15 is a cross-sectional side view of a microelectronic assembly that may include any of the embodiments disclosed herein.

FIG. 16 is a block diagram of an example electrical device that may include any of the embodiments disclosed herein.

### DETAILED DESCRIPTION

Die partitioning enables miniaturization of form factor and high-performance semiconductor packaging without some of the yield issues seen with other packaging methods, but die partitioning introduces technical challenges associated with providing fine die-to-die interconnections and operational communication in a package.

One approach to achieving the fine die-to-die interconnections is to scale the routing density in the organic substrate (e.g., implementing high density patterning (HDP) in conductive routing, wherein “high density” means a line and space interval of less than a conventional 9 micron and 12 micron L/S (e.g., in some embodiments, less than or equal to about 5 microns). However, HDP requires a high-resolution exposure that exhibits a narrow depth of focus (DoF), so implementing HDP requires new tools to pattern the finer features and precise control over the planarity of the organic substrate utilized.

The planarity of the organic substrate can be quantified as a total thickness variation (TTV). Future generations of HDP are anticipated to have increasingly stricter TTV requirements to enable the high-resolution exposure that will be needed. One proposed approach to meeting the stringent TTV requirements is to employ glass carriers. Glass carriers present a significant manufacturing challenge, as existing substrate infrastructure may not be well-suited for handling glass and may be costly to upgrade. Further, as patterning dimensions shrink, sensitivities to defects caused by foreign material (FM) become more pronounced. Thus, enabling high yield for HDP would require substantial improvements with regards to FM control within existing substrate manufacturing infrastructure.

A proposed solution for addressing the FM issue includes Z-disaggregation methods that typically rely on patterning sections of the organic substrate separately and then stitching known good sections together before assembly. However, Z-disaggregation methods are still uncertain and costly, and require further development to meet scale requirements. Thus, further technical solutions are desired to meet the challenges of future generations of HDP.

Embodiments disclosed herein propose a technical solution to the above-described technical problems in implementing HDP, in the form of a bumpless hybrid organic glass interposer. Provided embodiments pattern one or more HDP routing layers on a functional, thin, stitching medium, separate from the manufacturing of the organic substrate package. The HDP layer-stitching medium interposer is then attached to the organic substrate package utilizing well-established die bond films (DBFs) and/or die placement methods and tools. Embodiments achieve electrical connections between the HDP layer and underlying routing layer of the organic substrate by utilizing a self-align dry etch process through landing pads created with the HDP routing.

The provided embodiments offer several technological and economic advantages, a first being that the patterning of the HDP routing layer(s) can be performed separate from the substrate manufacturing process, infrastructure, and/or form factor. For example, the HDP routing can be patterned on a unit-sized stitched medium (relative to substrate) on an optional carrier in a higher-class clean room environment utilizing any form factor (wafer, quarter panel, etc.). Additionally, the stitched medium and an optional carrier can utilize a low TTV material (i.e., glass, etc.) for improved patterning tolerance of the HDP layer (as a result of narrower depth of focus exposure window). These approaches dispense with the need for organic substrates with a low TTV/warpage for patterning the HDP routing directly on the organic substrate. Other benefits of embodiments include a solderless-attach of the interposer to the substrate and ability to route the power from the bottom of the substrate through a self-aligned pillar to the top or front side. Advantageously, provided embodiments enable higher yield. These concepts are developed in more detail below.

Example embodiments are hereinafter be described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

Interposers and interconnect structures are referred to herein. As used herein, interposers are components that route signals between dies. In contrast, “interconnect structures” can comprise one or more conductive traces, one or more vias, or a combination thereof. The term conductive trace includes lateral signal routing and via contacts, which may be vertically oriented.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

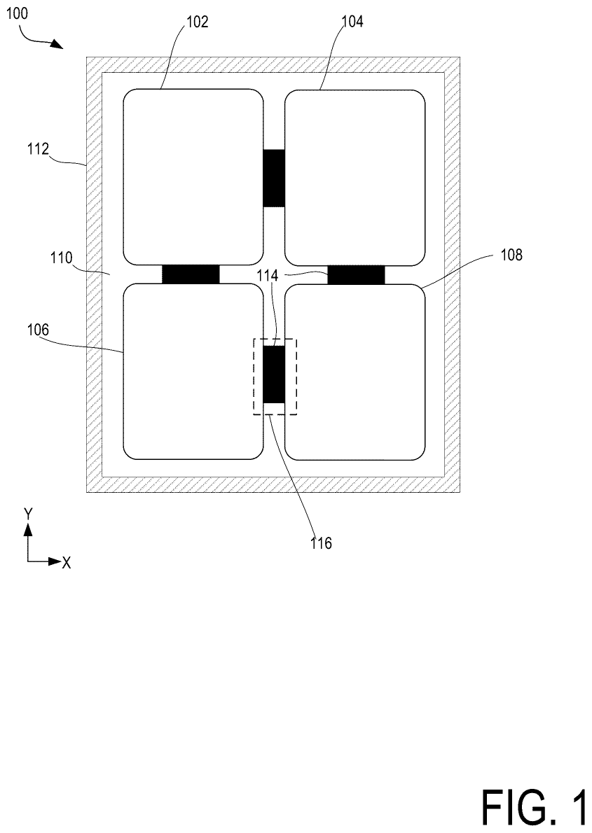

In the non-limiting example in FIG. 1, a multi-die assembly 100 comprises four die (die 102, die 104, die 106, and die 108). In other multi-die assemblies, there may be more or less than four die, and the die may be arranged in any fashion (e.g., square (e.g., 2×2, 4×4, 6×6), rectangular (e.g., 2×4, 3×5, 4×7)). The die may be attached to a package substrate 112, which may comprise a printed circuit board, thin-film substrate, or another suitable substrate.

In various embodiments, the die in the multi-die assembly 100 can be overmolded with an encapsulant 110. The encapsulant 110 can comprise molding compound, dielectric materials, metal, ceramic, plastic, or a combination thereof. Additionally, a thermal management solution (not shown) comprising a cooling component such as a vapor chamber, heat pipe, heat sink, or liquid-cooled cold plate may be attached to a multi-die assembly 100. As part of a thermal management solution, a thermal conduction layer interface material (TIM) may be located over the die 102, 104, 106, 108. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

The focus turns now to the die and their interconnections. The die 102, 104, 106, and 108, may be unpackaged integrated circuit die, and may alternatively be referred to as chips, chiplets, chip complexes, or chiplet complexes. While the terms die, chip, and chiplet may be used interchangeably, the term chiplet is sometimes used to refer to an integrated circuit die that implements a subset of the functionality of a larger integrated circuit component. Although the illustration depicts the chiplets as having uniform dimensions, in practice, chiplet dimensions (lateral dimensions, as well as thickness) and shape can vary among chiplets; moreover, the chiplets may vary by type/functionality (e.g., compute, memory, I/O, power management (controlling the delivery of power and/or providing power to components)). Any integrated circuit die, chip, or chiplet can implement any portion of the functionality of any processor unit described or referenced herein. Furthermore, a multi-die assembly 100 can have any shape, such as a substantially square shape, substantially rectangular shape or substantially circular shape.

The use of chiplets in integrated circuit components has become attractive as feature sizes have reduced and the demand for high-performance larger integrated circuit components has increased. The approach of assembling multiple known-good dies (chiplets) to form a larger integrated circuit component can result in improved manufacturing efficiencies, as the overall yield of an integrated circuit component assembled from multiple small chiplets is better than that of an integrated circuit component in which the functionality of the chiplets is implemented on a single large integrated circuit die. When the multi-die assembly 100 implements a large and/or complex integrated circuit component formed using one or more chiplets, the performance and size of the interposers 114 becomes more significant.

Provided embodiments of the interposer 114 may be manufactured separately from the manufacture of the substrate 112 and/or of the die. The separate manufacture of the interposer 114 allows for the creation of interposers 114 with internal features (e.g., vias, pads, conductive traces) with geometries (e.g., via width/space, conductive trace width/space/thickness) that can be smaller than the geometries of similar features in a substrate. In an example, the interposer 114 can support finer bump pitches than a die pitch (e.g., pitches of 25 microns or less).

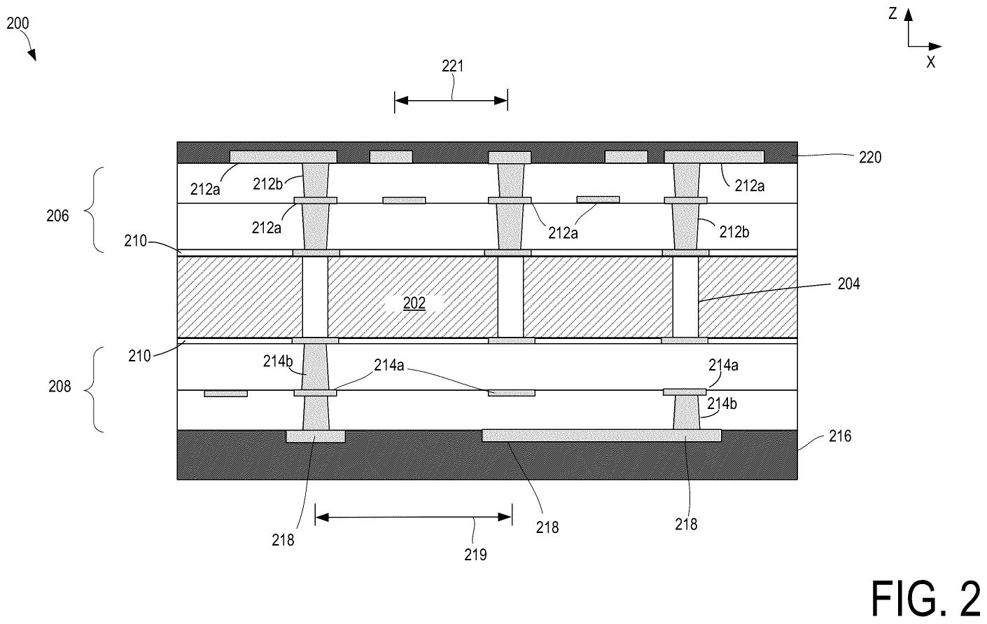

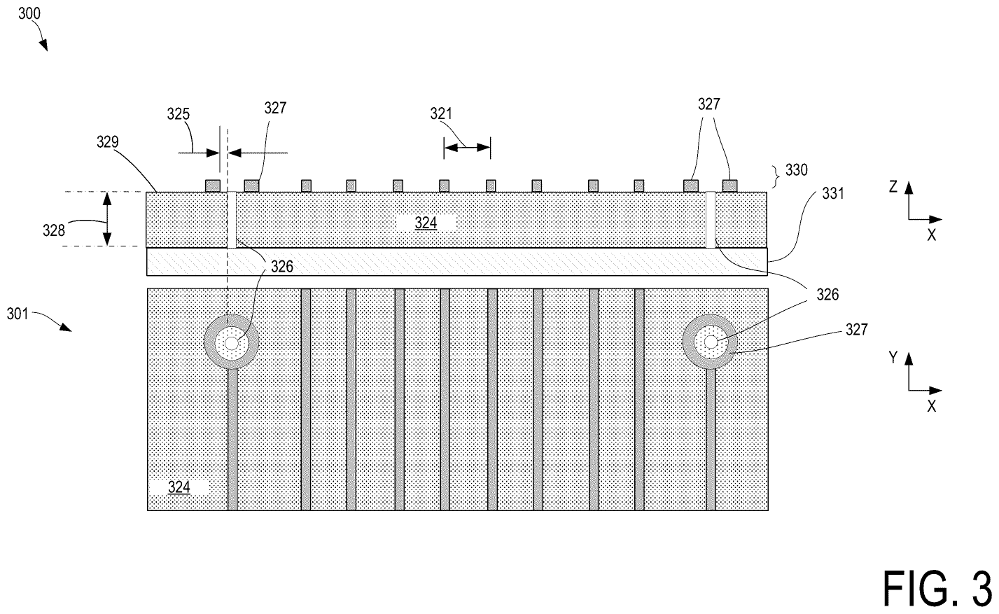

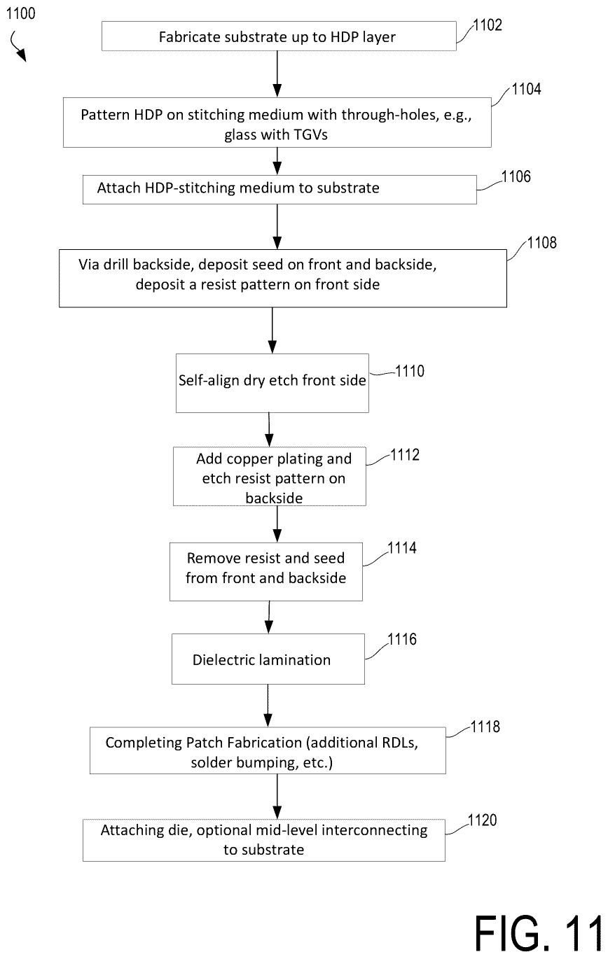

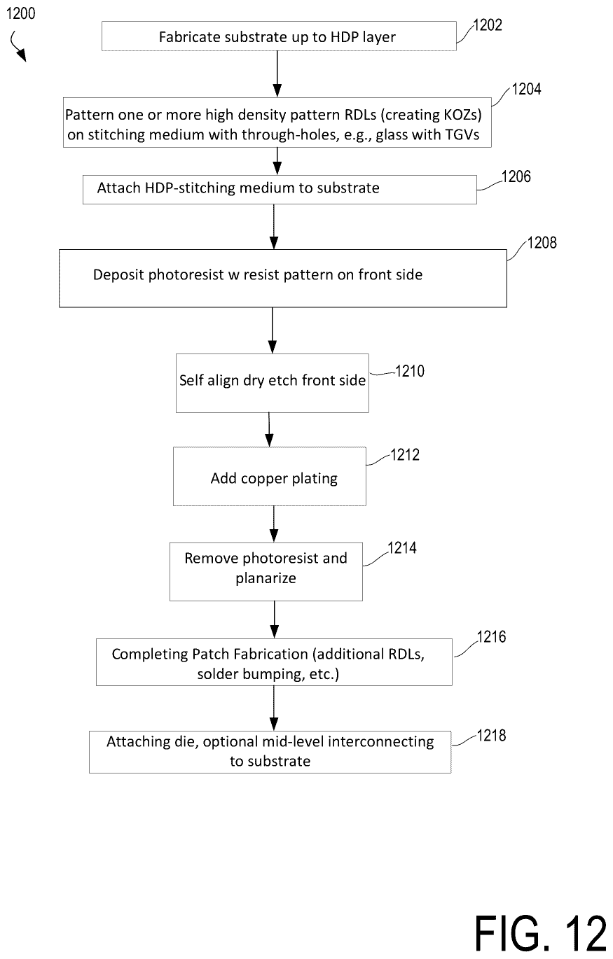

The dashed line 116 narrows the focus to an area of the substrate 112 that includes an interposer 114 that implements HDP on a stitching medium. To facilitate the interposer 114 discussion, a non-limiting example of a substrate patch is first described (FIG. 2, patch 200). FIGS. 3-10 provide various embodiments and stages of development of the interposer 114 and may reference the substrate patch 200. FIGS. 11 and 12 provide a process flow for creating embodiments described herein.

The substrate patch 200 may be manufactured separately from the interposer 114 and in accordance with conventional methodologies. The substrate patch 200 is fabricated up to the HDP layer (at process flow 11, 1102). In the exemplary substrate patch 200, an epoxy core 202 may comprise glass fibers, and have conductive vias 204 therethrough. In various embodiments, the substrate patch 200 may comprise multiple dielectric layers or redistribution layers (RDLs) and multiple conductive traces layered on the core 202. In the example shown in FIG. 2, substrate patch 200 comprises conductive traces 212 (vertical 212b and lateral 212a) located in one or more dielectric layers 206 built up (in a Z direction in the figure) on a top surface or front side of the core 202, and conductive traces 214 (vertical 214b and lateral 214b), located in one or more dielectric layers 208 on a back side of the core 202, respectively. Conductive traces 212 and 214 comprise electrically conductive material, such as, a metal (e.g., copper, aluminum, nickel, cobalt, iron, tin, gold, silver, or combinations thereof) or another suitable conductive material, and provide electrically conductive paths from an origin to a terminus of the respective trace. The dielectric layers 206 and 208 can be a suitable nitride or oxide, such as silicon dioxide (SiO₂), carbon-doped silicon dioxide, fluorine-doped silicon dioxide, hydrogen-doped silicon dioxide, or silicon nitride.

At an upper surface of the substrate patch 200, a thin encapsulation layer 220 may overlay one or more conductive traces and/or contacts separated from each other at a first pitch 221, and at a lower surface, a standard encapsulation layer 216 may overlay one or more traces or conductive pads separated from each other at a second pitch 219. In various embodiments, the first pitch is a fine pitch, and the second pitch is a coarse pitch.

As used herein, “pitch” means the physical distance at which a feature is repeated (e.g., the space from the center of one instance of a feature to the center of an adjacent instance of the feature). As used herein “fine pitch” generally means a die-scale pitch (e.g., first pitch 221 on upper surface of the substrate patch 200). Fine pitch dimensions may include a range of about 0.001 mm to about 0.3 mm. In some embodiments, features having a fine pitch have dimensions of about 1 μm (micron) or less. In other embodiments, features having a fine pitch may have dimensions of about 0.5 μm or less. In addition to the conductive contacts that are used to attach integrated circuit dies to a substrate patch, other features that can have a fine pitch include the vias in one or more RDLs adjacent to the pinouts for integrated circuit dies.

In contrast, “coarse pitch” generally means a package-level pitch, which is larger than a fine pitch. For example, pitch 219 may be a coarse pitch. The coarse pitch geometries may be for a ball grid array (BGA) or a land grid array (LGA). In various embodiments, a BGA pitch is in a range of about 0.1 mm to about 1 mm, and LGA pitch is in a range of about 0.1 mm to about 1 mm.

In practice, the exemplary substrate patch 200 may be part of a substrate or PCB that provides electrically conductive paths between one or more electrical contacts located on a front side of the substrate patch 200, through respective vias 204 in a core 202, to a lower surface or back side of the substrate patch 200. In various embodiments described herein, the substrate patch, substrate, or PCB, is separately fabricated up to the HDP layer. Provided embodiments build the interposer 114 for attaching on a specific substrate patch, substrate, or PCB.

We turn next to the separate construction of an interposer with the desired HDP layer that can be transferred to the substrate patch. The interposer is built (vertically, or in the Z direction in the figures) on a stitching medium. In FIG. 3, view 300 is a simplified cross-sectional view (i.e., the Z-X direction in the figures) of the stitching medium embodied as a glass layer 324 with the HDP located on the front side or upper surface, and view 301 is a simplified top view (i.e., the upper surface or front side) of the glass layer 324, viewed in the X-Y direction in the figures.

The glass layer 324 may comprise glass, (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO₂, Al₂O₃, B₂O₃, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles. Glass layer 324 may comprise multiple glass sheets bonded together with an adhesion layer. In various embodiments, the glass layer 324 may have thickness 328 in a range of about 20 microns to about 1 millimeter, +/−10%.

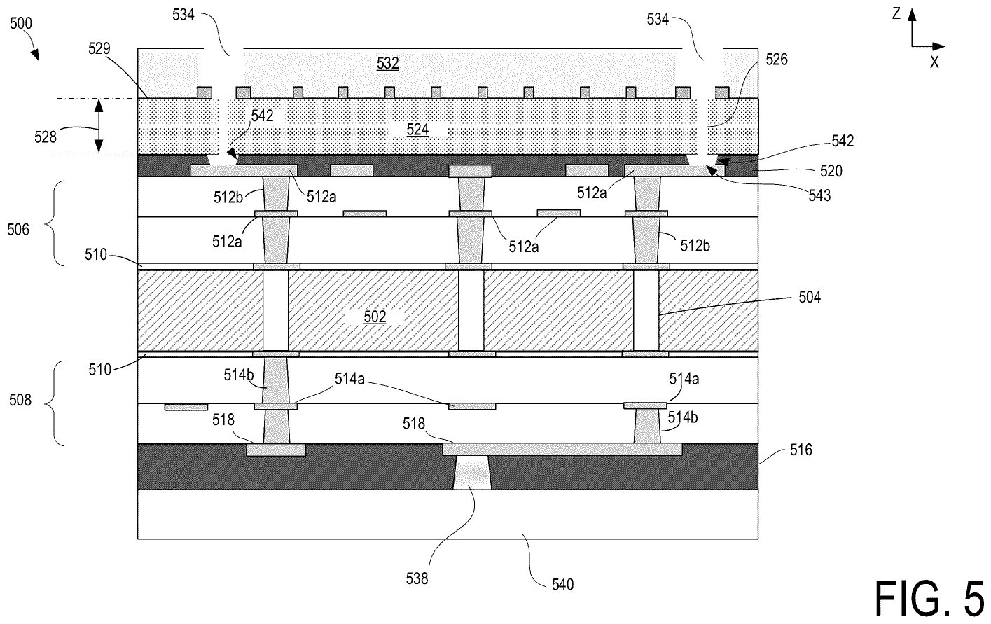

The glass layer serves the function of a mask when placed on a substrate patch, as described in connection with FIG. 5. At least one through-hole or through glass via (TGV) 326 extends substantially perpendicularly from the front side or upper surface of the glass layer 324 to the back side or lower surface of the glass layer 324, and functions as an opening in the mask of the glass layer 324. The location of the TGV 326 may be selected to align the interposer on a substrate patch and to secure electrical connection between the HDP in the interposer and the substrate patch, as is described in more detail below. The TGVs 326 may have a diameter of about 10 to about 150 microns.

The HDP/HDP layer includes a conductive routing material or redistribution layer (RDL); in various embodiments, the HDP layer is patterned to meet a line and spacing requirement of less than 5 microns. The conductive routing material may be a metal layer comprising conductive vias and traces (or metal lines), metals used for interconnect metals in the RDL include copper or other suitable metal.

In various embodiments, the HDP layer can include, overlaid on the conductive routing material, a dielectric material, such as, a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, an HDP layer comprises a photo-imageable dielectric (PID). In some embodiments, an HDP layer comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

In some embodiments, it is advantageous for the HDP layer to have a CTE that matches that of target integrated circuit dies (e.g., match the CTE of silicon) attached to a substrate or PCB. In some embodiments, the dielectric material of the HDP layer can have a CTE that is close (e.g., within 10%) to that of silicon. In other embodiments, the dielectric material of HDP layer can be any type of epoxy molding compound.

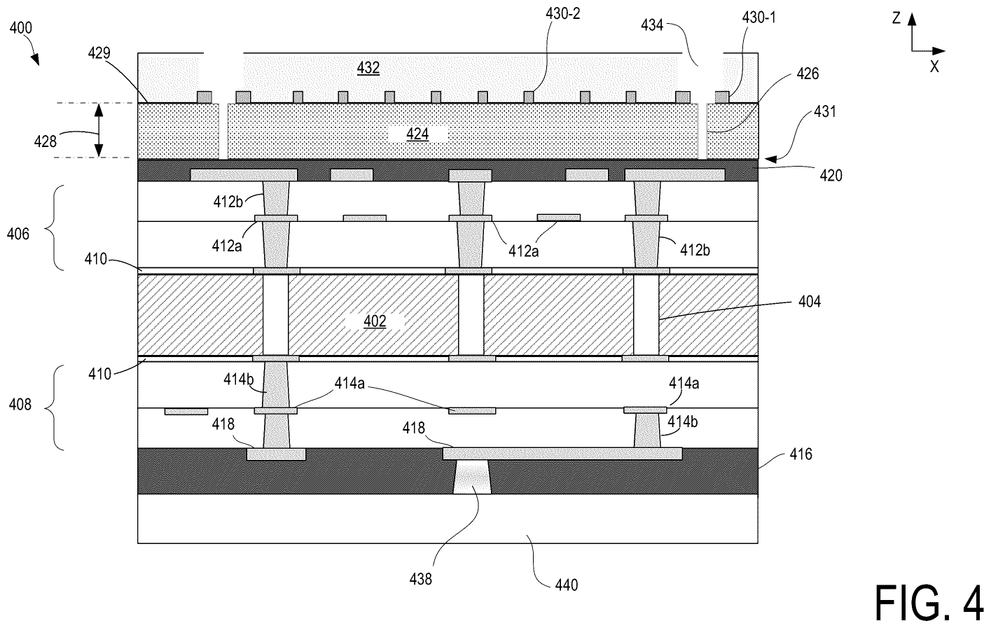

In various embodiments, the interposer fabrication is performed in a fabrication facility with a higher-level clean room than that which is used for the fabrication of the substrate patch 200. This methodology of separate fabrication supports the HDP process and enables a higher yield of the final product. In the example embodiment shown in FIG. 3, the front side or upper surface 329 of the glass layer 324 is patterned with a single layer of HDP 330 (indicated in FIG. 4 with traces 430-2). The HDP may comprise a metal (e.g., copper, aluminum, nickel, cobalt, iron, tin, gold, silver, or combinations thereof) or another suitable conductive material.

In addition to patterned conductive traces 327, the conductive routing material frames the at least one TGV 326 with an offset 325 (the framing is further indicated in FIG. 4 with traces 430-1). Viewed in a top-down or X-Y perspective, the conductive routing of the HDP forms a generally annular ring around each TGV 326 present in the stitching medium (process flow 1100, at 1104). Note that the annular rings 327 of HDP are to enable a self-align dry etch process and accommodate processing tools, and therefore have a larger diameter than the respective opening of the TGV; this overlay tolerance is an alignment offset, indicated with offset 325 extending radially around the openings of the TGVs 326. The size of the offset 325 may be a function of the exposure tool capability used in fabrication. In various embodiments, the offset 325 may be in a range of about 0.05 microns to 2 microns.

As illustrated in FIG. 3, embodiments may be built on an optional carrier 331. When an optional carrier 331 is utilized, a releasable bonding film (not shown) may be employed to attach the stitching medium to the carrier, such that the stitching medium or glass layer 324 can be readily released from the carrier 331 and placed on the substrate patch 200 later in manufacturing. The optional carrier 331 may be glass or any other suitable material to provide appropriate stiffness and planarity for the HDP process.

The embodiment 400 of FIG. 4 is a non-limiting example of an interposer based on the structure illustrated in FIG. 3 (stitching medium with the single layer of HDP) attached to the substrate patch 200 (see, FIG. 11 process flow 1100, at 1106). The interposer comprising the HDP layer and glass layer can be placed onto the substrate patch 200 using conventional pick and place die placement and bonding with a die bond film (DBF) (not shown for simplicity), combined with self-alignment or passive alignment techniques with the TGVs.

FIGS. 4-10 build upon concepts described above and repeatedly use analogous features. Accordingly, many of the components from FIGS. 4-10 are reproduced from FIGS. 2-3, as is observable with a comparison of shapes, locations, and context. For example, dielectric layers 206, 406, 506, 606, and 706 are analogous, as are dielectric layers 208, 408, 508, 608, and 708 are analogous, conductive traces 212 and 214 have respective analogous objects in 412, 414, 512, 514, 612, 614, and 612 and 614; thin encapsulations layers 220, 420, 520, 620, and 720 are analogous; standard encapsulation layers 216, 416, 516, 616, and 716 are analogous; glass cores 324, 424, 524, 624, 724, 824, 924, and 1024 are analogous; TGVs 326, 426, 526, 626, 726, 826, 926, and 1026 are analogous; conductive contacts 218, 418, 518, 618, 718, and 818 are analogous; and, etc.

At 1108, the back side of embodiment 400 may be via drilled, as indicated with via 438. Also, at 1108, a seed layer and a resist 432 layer may be deposited on the front side (top surface 429). The resist 432 layer comprises a thickness sufficient to compensate for the dry etch process. In various embodiments, the thickness of the resist may be between 5 microns and 60 microns. The resist 432 layer may comprise a resist pattern, including openings 434 that are coaxially aligned with, and have a larger diameter than, an inner diameter of the annular HDP rings that surround the TGVs 426, as illustrated; additionally, at 1108, a resist 440 layer may be overlaid or located on the back side.

At 1110, a self-align dry etch is performed on the front side or top surface 429. This is illustrated in FIG. 5, subsequent to, and caused by, the self-align dry etch processing, the resist or dielectric within the volume created by the diameter of the annular rings is removed (e.g., 534) and the dry etch extends through the openings of the TGVs 526 into dielectric layer 520 where it exposes the underlying material of traces or pads (at surface 543). The non-limiting example of FIG. 5 illustrates two of these openings, which are by design coaxial with the annular HDP formations around openings of TGVs 526 described above. This figure illustrates the way in which the glass layer 524 acts as a mask layer for the substrate patch that it is placed on because only openings in the glass layer 524 permit self-align dry etch into the substrate patch.

Further, as indicated by the location of the volume 542 to which the arrow points, the vertical or Z direction walls of volume 542 are substantially straight but sloped from the top of dielectric 520 to the surface 543, giving the volume a larger diameter (or width in two dimensions) at the top of dielectric 520, and a smaller diameter or narrower width at the surface 543. Embodiments produced with this self-aligned dry etch methodology create a plug or volume 542 with substantially straight walls and a substantially trapezoidal shape in two dimensions (Z-X plane, as illustrated); this is a feature that may be observed in microscopic images. Embodiments achieve electrical connections between the HDP layer and underlying routing layer of the substrate by utilizing a self-align dry etch process through landing pads connected to the HDP routing to create this feature referred to herein as a plug.

In contrast, methodologies other than self-aligned dry etch would likely result in a volume having curved walls in the Z-X plane and a rounded or oval shape when viewed in the Z-X plane. Resist 540 layer may be overlaid on the back side during this process, or earlier, when resist 532 layer is being deposited and patterned.

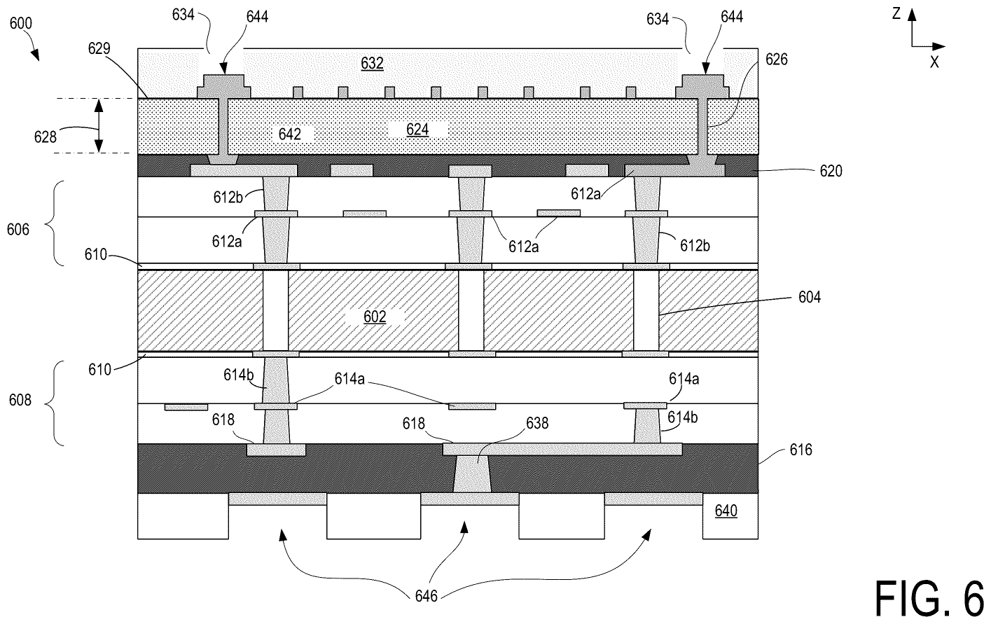

Having strategically opened up or exposed the traces 512a in the dielectric 520, conductive material can be filled into the openings, providing an electrical communication path between HDP and the substrate patch, and also anchoring and/or aligning the stitching medium or interposer onto the substrate patch. Turning to FIG. 6, At 1112, copper plating is added, filling in opening 626, and creating an electrically conductive path between a pad 644 and the conductive material of the traces 612a. Also at 1112, a resist pattern can be etched on the resist 640 on the back side and openings in the resist 640 may be filled with a conductive material (638 and 646). In various embodiments, the copper plating of the front side (upper surface) and back side may be performed at the same time.

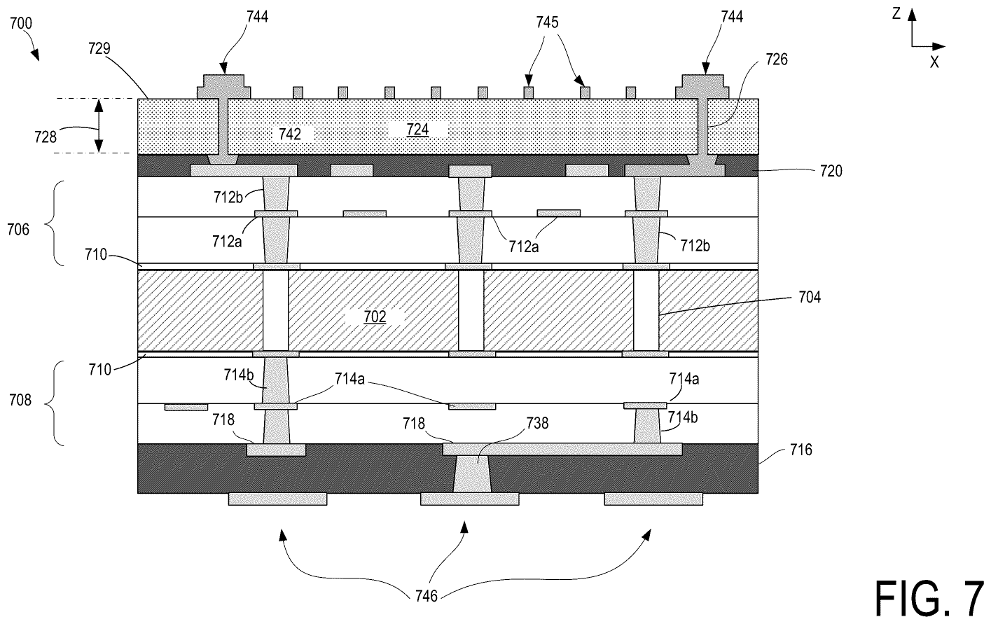

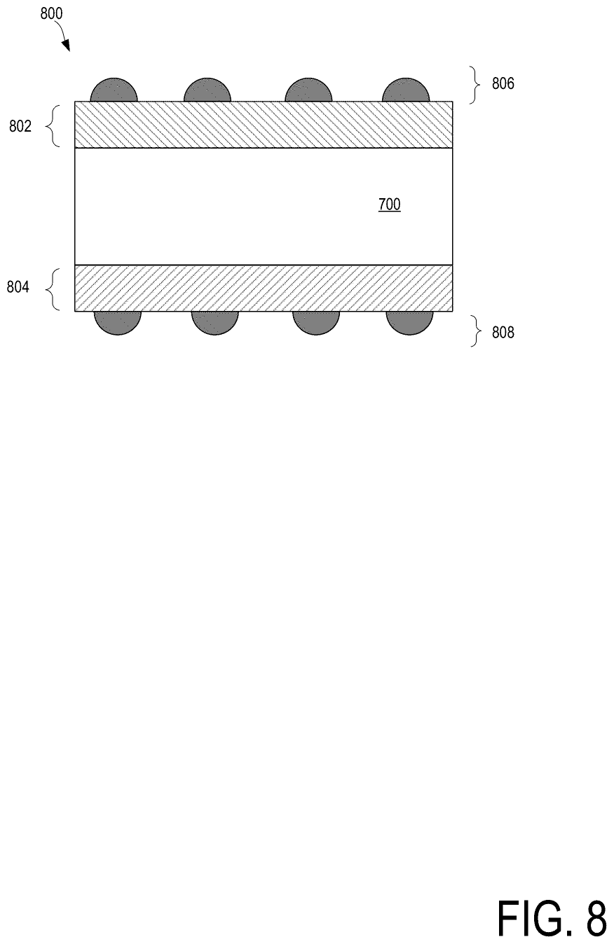

In FIG. 7, and at 1114, the resist 632 and resist 640 are removed from the front and back side. Pads 744 and traces 745 are exposed on the top surface and pads 746 are exposed on the back side. From FIG. 7, further processing or fabrication may be performed on embodiment 700. For example, as shown in FIG. 8, embodiment 700 may have one or more layers 802 added to the front side, and one or more layers 804 may be added to the back side. In an embodiment, the layers 802 and 804 may comprise a dielectric laminate (at 1116). Additionally, at 1118, the substrate patch may undergo further patch fabrication, in which case, layers 802 and 804, in addition to dielectric lamination, may include one or more dielectric layers comprising redistribution layers (RDL). At 1118 embodiment 800 may also undergo a solder bumping process (adding solder bumps 806 on a top surface and solder bumps 808 on the lower surface or back side). In various embodiments, any dielectric and RDL used in layers 804 and 806 are similar to those described in connection with FIGS. 2 206 and 208.

At 1120, optionally, one or more die may be attached to the substrate patch. Responsive to 1120, the resulting structure may be a complete substrate, such as, for a system on chip (SoC).

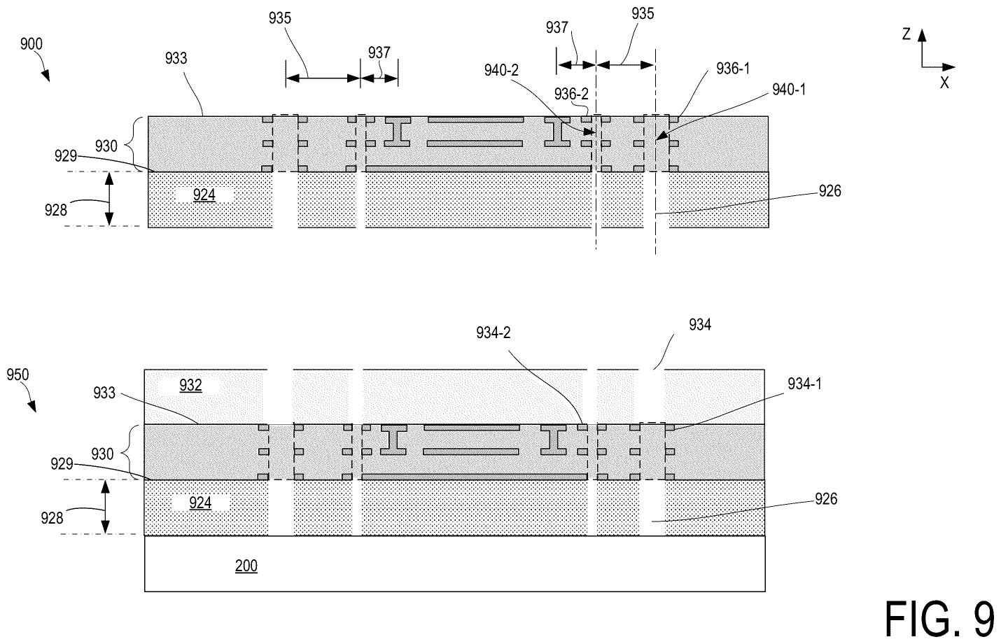

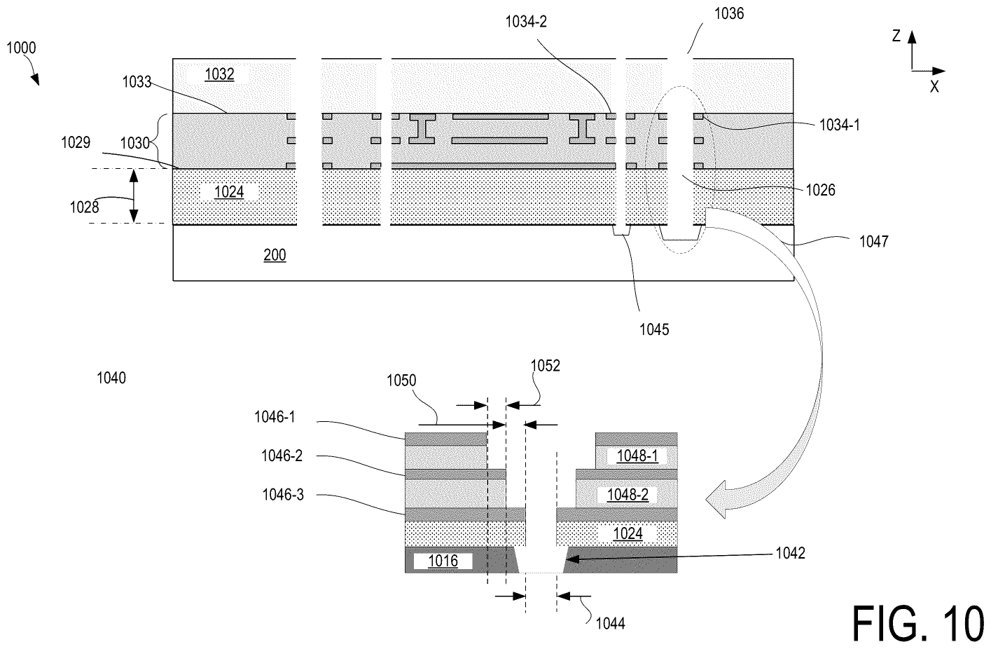

In various other embodiments, instead of one HDP layer, multiple HDP layers are built up (in the Z direction in the figures) on the stitching medium or glass layer. FIGS. 9-10 are simplified illustrations depicting various stages of development of an interposer with a multiple layers of HDP combined with the substrate patch from FIG. 2. FIG. 12 illustrates an example process for a method for manufacturing and implementing an interposer with multiple layers of HDP, in accordance with various embodiments. Once again, the substrate patch 200 is fabricated at a first line and space interval, up to where a second line and space interval (the HDP layer) is desired (at 1202). In various embodiments, the second line and space interval is less than the first line and space interval, e.g., 5 microns or less.

At 1204, one or more high-density pattern RDLs are built up on the front side of the glass layer, wherein the back side of the glass layer is attached to a stitching medium. In a non-limiting example shown in FIG. 9, the HDP 930 layer on the stitching medium 924 comprises three layers of HDP. With attention on embodiment 901, the cross-sectional area inside the annular ring 327 (and any additional intended electrical communication paths in the Z direction in the figures) contributes to a three dimensional keep out zone when multiple HDP layers are built up. A keep out zone 940-1 is created with stacked annular rings 936-1 of HDP, and a keep out zone 940-2 of a smaller diameter is created with stacked annular rings of HDP 936-2. For illustrative purposes, these keep out zones have different diameters and different pitches, as indicated with pitch 935 and pitch 937; however, in other embodiments, additional diameters and pitches may be supported. The HDP layers are illustrated as if the keep out zones have straight vertical walls, however, in practice, the overlay tolerance described above may be implemented, and each annular ring may be progressively larger in diameter than the one underneath it by about 2 microns (moving upwards in the Z direction in the figures). In a non-limiting example, a first annular ring may be 12 microns in diameter, located on a surface of the glass layer 924, a second annular ring may be 14 microns in diameter, and a third annular ring may be 16 microns in diameter.

At 1206, the interposer including the glass layer 924 and the HDP layers 930 is attached to the substrate patch. Embodiment 950 illustrates the embodiment 900 attached to the substrate patch 200. Embodiment 950 further illustrates a patterned resist layer 932 located on the top surface 933 of the HDP layers 930 (at 1208).

The patterned resist layer 932 of the embodiment 950 is self-aligned dry etched at 1210, resulting in a structure as illustrated in FIG. 10, embodiment 1000. As described in connection with FIG. 5, a volume 1042 (and a volume 1045) is opened up in the thin laminate 1016 over conductive tracing in the substrate patch is exposed by the self-align dry etch process. Additionally, as with volume 542, the volume 1042 has the substantially straight and sloped walls described above in connection with FIG. 5, volume 542. When the volume 1042 is filled or plated with electrically conductive material such as a metal or copper, it may be referred to as a “plug.” As may be appreciated, the plug 1042 is substantially coaxial with the TGV 1026 and secures, with a substantially perpendicular contact, an electrical path between the HDP routing on the stitching layer and the conductive tracing in the substrate patch.

A structure encircled by the dashed oval 1047 is shown enlarged at the bottom of the page to address any potential overlay alignment error between multiple RDL in the HDP. Each RDL of the HDP layer may have a respective overlay delta of about 0.05 microns to about 2 microns. The TGV opening may have a diameter of about 10 microns to about 100 microns.

In a non-limiting example, a structure 1047 comprises glass layer 1024 with a TGV 1026 having a diameter 1044 of about 30 microns to about 70 microns, the glass layer 1024 thickness is about 200 microns, three metal layers 1046-1,1046-2,1046-3 are each about 5 microns thick, the dielectric layers 1048-1, 1048-2, and 1016 are each about 5 microns thick, collectively making about 30 microns (in the Z direction in the figure) of thickness to be etched. The first overlay delta 1050 and the second overlay delta 1052 may each independently from one another be in a range of about 0.05 microns to about 2 microns. The AR filter for plating this structure may range from 8:1 when the diameter 1044 is about 30 microns to 3:1 when the diameter 1044 is about 70 microns.

The embodiment 1000 may be subjected to further manufacturing. An exemplary process flow follows the process flow detailed in connection with FIGS. 6, 7, and 8. For example, the copper plating may be added at 1212, photoresist may be removed and planarized at 1214, patch fabrication may be completed at 1216, and die may be attached at 1218. At the completion of 1218, the end product may be a SoC or other multi-die assembly.

Thus, various non-limiting embodiments of a bumpless hybrid organic glass interposer have been described. The disclosed embodiments pattern one or more HDP routing layers on a functional, thin, carrier, separate from the organic substrate package. The HDP layer(s) is/are then attached to the substrate package utilizing well-established die bond films (DBFs) and/or die placement methods and tools. The following description provides additional detail and context for the intended die and various package assembly and device configurations that can be created based on or using the provided bumpless hybrid organic glass interposer.

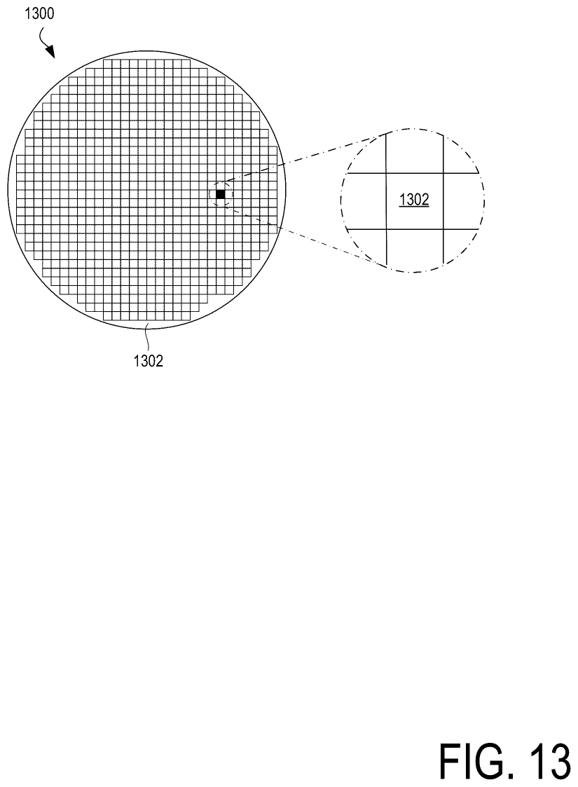

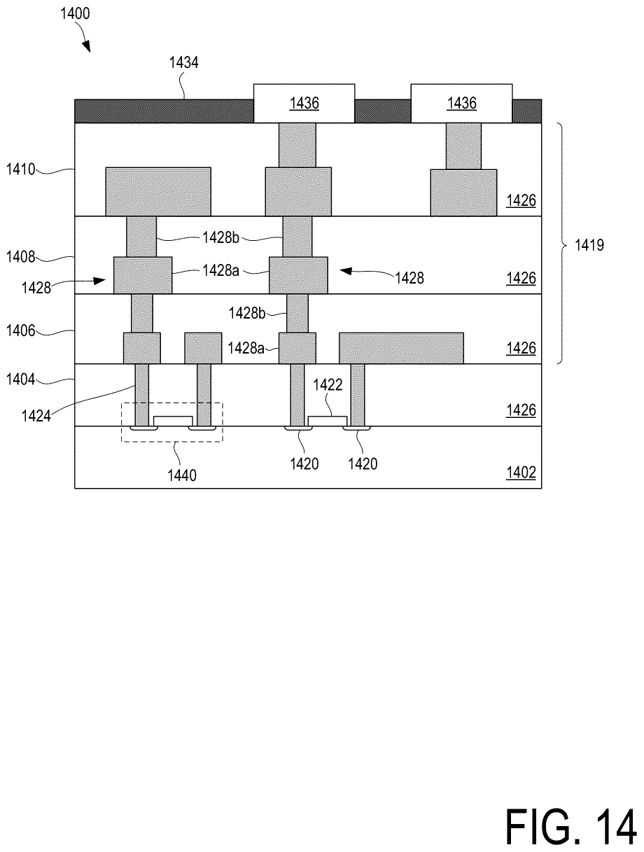

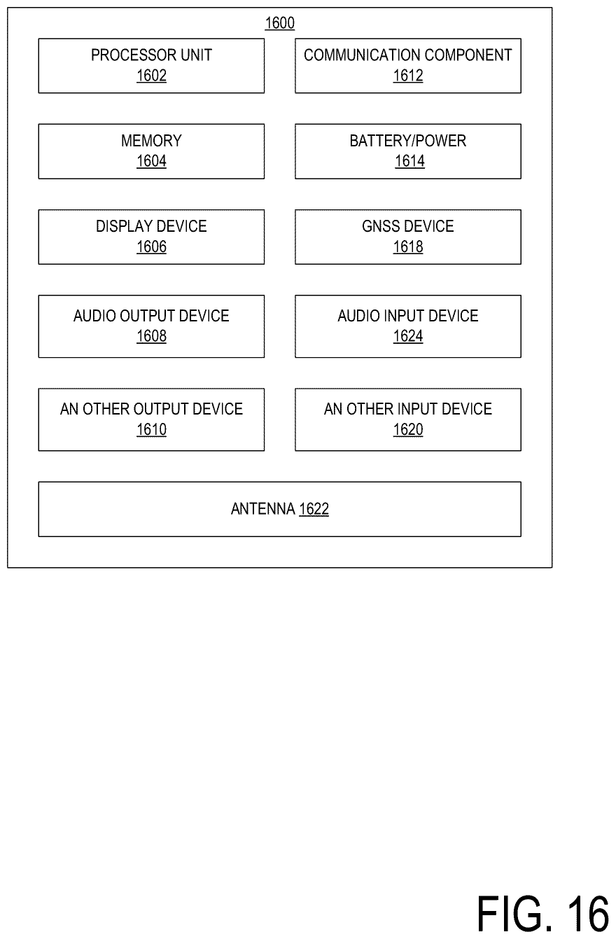

FIG. 13 is a top view of a wafer 1300 and dies 1302 that may be included in any of the embodiments disclosed herein. The wafer 1300 may be composed of semiconductor material and may include one or more dies 1302 formed on a surface of the wafer 1300. After the fabrication of the integrated circuit components on the wafer 1300 is complete, the wafer 1300 may undergo a singulation process in which the dies 1302 are separated from one another to provide discrete “chips” or destined for a packaged integrated circuit component. The individual dies 1302, comprising an integrated circuit component, may include one or more transistors (e.g., some of the transistors 1440 of FIG. 14, discussed below), supporting circuitry to route electrical signals to the transistors, passive components (e.g., signal traces, resistors, capacitors, or inductors), and/or any other integrated circuit components. In some embodiments, the wafer 1300 or the die 1302 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 1302. For example, a memory array formed by multiple memory devices may be formed on a same die 1302 as a processor unit (e.g., the processor unit 1602 of FIG. 16) or other logic that is configured to store information in the memory devices or execute instructions stored in the memory array. In some embodiments, a die 1302 may be attached to a wafer 1300 that includes other die, and the wafer 1300 is subsequently singulated, this manufacturing procedure is referred to as a die-to-wafer assembly technique.

FIG. 14 is a cross-sectional side view of an integrated circuit 1400 that may be included in any of the embodiments disclosed herein. One or more of the integrated circuits 1400 may be included in one or more dies 1302 (FIG. 13). The integrated circuit 1400 may be formed on a die substrate 1402 (e.g., the wafer 1300 of FIG. 13) and may be included in a die (e.g., the die 1302 of FIG. 13).

The die substrate 1402 may be a semiconductor substrate composed of semiconductor material systems including, for example, n-type or p-type materials systems (or a combination of both). The die substrate 1402 may include, for example, a crystalline substrate formed using a bulk silicon or a silicon-on-insulator (SOI) substructure. In some embodiments, the die substrate 1402 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1402. Although a few examples of materials from which the die substrate 1402 may be formed are described here, any material that may serve as a foundation for an integrated circuit 1400 may be used. The die substrate 1402 may be part of a singulated die (e.g., the dies 1302 of FIG. 13) or a wafer (e.g., the wafer 1300 of FIG. 13).

The integrated circuit 1400 may include one or more device layers 1404 disposed on the die substrate 1402. The device layer 1404 may include features of one or more transistors 1440 (e.g., metal oxide semiconductor field-effect transistors (MOSFETs)) formed on the die substrate 1402. The transistors 1440 may include, for example, one or more source and/or drain (S/D) regions 1420, a gate 1422 to control current flow between the S/D regions 1420, and one or more S/D contacts 1424 to route electrical signals to/from the S/D regions 1420.

The gate 1422 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1440 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1440 along the source-channel-drain direction, the gate electrode may comprise a U-shaped structure that includes a bottom portion substantially parallel to the surface of the die substrate 1402 and two sidewall portions that are substantially perpendicular to the top surface of the die substrate 1402. In other embodiments, at least one of the metal layers that form the gate electrode may simply be a planar layer that is substantially parallel to the top surface of the die substrate 1402 and does not include sidewall portions substantially perpendicular to the top surface of the die substrate 1402. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 1420 may be formed within the die substrate 1402 adjacent to the gate 1422 of individual transistors 1440. The S/D regions 1420 may be formed using an implantation/diffusion process or an etching/deposition process, for example. In the former process, dopants such as boron, aluminum, antimony, phosphorous, or arsenic may be ion-implanted into the die substrate 1402 to form the S/D regions 1420. An annealing process that activates the dopants and causes them to diffuse farther into the die substrate 1402 may follow the ion-implantation process. In the latter process, the die substrate 1402 may first be etched to form recesses at the locations of the S/D regions 1420. An epitaxial deposition process may then be conducted to fill the recesses with material that is used to fabricate the S/D regions 1420. In some implementations, the S/D regions 1420 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1420 may be formed using one or more alternate semiconductor materials such as germanium or a group III-V material or alloy. In further embodiments, one or more layers of metal and/or metal alloys may be used to form the S/D regions 1420.

Electrical signals, such as power and/or input/output (I/O) signals, may be routed to and/or from the devices (e.g., transistors 1440) of the device layer 1404 through one or more interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with the interconnect structures 1428 of the interconnect layers 1406-1410. The one or more interconnect layers 1406-1410 may form a metallization stack (also referred to as an “ILD stack”) 1419 of the integrated circuit 1400.

The interconnect structures 1428 may be arranged within the interconnect layers 1406-1410 to route electrical signals according to a wide variety of designs; in particular, the arrangement is not limited to the particular configuration of interconnect structures 1428 depicted in FIG. 14. Although a particular number of interconnect layers 1406-1410 is depicted in FIG. 14, embodiments of the present disclosure include integrated circuits having more or fewer interconnect layers than depicted.

In some embodiments, the interconnect structures 1428 may include lines 1428a and/or vias 1428b filled with an electrically conductive material such as a metal. The lines 1428a may be arranged to route electrical signals in a direction of a plane that is substantially parallel with a surface of the die substrate 1402 upon which the device layer 1404 is formed. For example, the lines 1428a may route electrical signals in a direction in and out of the page and/or in a direction across the page. The vias 1428b may be arranged to route electrical signals in a direction of a plane that is substantially perpendicular to the surface of the die substrate 1402 upon which the device layer 1404 is formed. In some embodiments, the vias 1428b may electrically couple lines 1428a of different interconnect layers 1406-1410 together.

The interconnect layers 1406-1410 may include a dielectric material 1426 disposed between the interconnect structures 1428, as shown in FIG. 14. In some embodiments, dielectric material 1426 disposed between the interconnect structures 1428 in different ones of the interconnect layers 1406-1410 may have different compositions; in other embodiments, the composition of the dielectric material 1426 between different interconnect layers 1406-1410 may be the same. The device layer 1404 may include a dielectric material 1426 disposed between the transistors 1440 and a bottom layer of the metallization stack as well. The dielectric material 1426 included in the device layer 1404 may have a different composition than the dielectric material 1426 included in the interconnect layers 1406-1410; in other embodiments, the composition of the dielectric material 1426 in the device layer 1404 may be the same as a dielectric material 1426 included in any one of the interconnect layers 1406-1410.

A first interconnect layer 1406 (referred to as Metal 1 or “M1”) may be formed directly on the device layer 1404. In some embodiments, the first interconnect layer 1406 may include lines 1428a and/or vias 1428b, as shown. The lines 1428a of the first interconnect layer 1406 may be coupled with contacts (e.g., the S/D contacts 1424) of the device layer 1404. The vias 1428b of the first interconnect layer 1406 may be coupled with the lines 1428a of a second interconnect layer 1408.

The second interconnect layer 1408 (referred to as Metal 2 or “M2”) may be formed directly on the first interconnect layer 1406. In some embodiments, the second interconnect layer 1408 may include via 1428b to couple the lines 1428 of the second interconnect layer 1408 with the lines 1428a of a third interconnect layer 1410. Although the lines 1428a and the vias 1428b are structurally delineated with a line within individual interconnect layers for the sake of clarity, the lines 1428a and the vias 1428b may be structurally and/or materially contiguous (e.g., simultaneously filled during a dual-damascene process) in some embodiments.

The third interconnect layer 1410 (referred to as Metal 3 or “M3”) (and additional interconnect layers, as desired) may be formed in succession on the second interconnect layer 1408 according to similar techniques and configurations described in connection with the second interconnect layer 1408 or the first interconnect layer 1406. In some embodiments, the interconnect layers that are “higher up” in the metallization stack 1419 in the integrated circuit 1400 (i.e., farther away from the device layer 1404) may be thicker that the interconnect layers that are lower in the metallization stack 1419, with lines 1428a and vias 1428b in the higher interconnect layers being thicker than those in the lower interconnect layers.

The integrated circuit 1400 may include a solder resist material 1434 (e.g., polyimide or similar material) and one or more conductive contacts 1436 formed on the interconnect layers 1406-1410. In FIG. 14, the conductive contacts 1436 are illustrated as taking the form of bond pads. The conductive contacts 1436 may be electrically coupled with the interconnect structures 1428 and configured to route the electrical signals of the transistor(s) 1440 to external devices. For example, solder bonds may be formed on the one or more conductive contacts 1436 to mechanically and/or electrically couple an integrated circuit die including the integrated circuit 1400 with another component (e.g., a printed circuit board). The integrated circuit 1400 may include additional or alternate structures to route the electrical signals from the interconnect layers 1406-1410; for example, the conductive contacts 1436 may include other analogous features (e.g., posts) that route the electrical signals to external components.

In some embodiments in which the integrated circuit 1400 is a double-sided die, the integrated circuit 1400 may include another metallization stack (not shown) on the opposite side of the device layer(s) 1404. This metallization stack may include multiple interconnect layers as discussed above with reference to the interconnect layers 1406-1410, to provide electrically conductive paths (e.g., including conductive lines and vias) between the device layer(s) 1404 and additional conductive contacts (not shown) on the opposite side of the integrated circuit 1400 from the conductive contacts 1436.

In other embodiments in which the integrated circuit 1400 is a double-sided die, the integrated circuit 1400 may include one or more through-silicon vias (TSVs) through the die substrate 1402; these TSVs may make contact with the device layer(s) 1404, and may provide electrically conductive paths between the device layer(s) 1404 and additional conductive contacts (not shown) on the opposite side of the integrated circuit 1400 from the conductive contacts 1436. In some embodiments, TSVs extending through the substrate can be used for routing power and ground signals from conductive contacts on the opposite side of the integrated circuit 1400 from the conductive contacts 1436 to the transistors 1440 and any other components integrated into the die 1400, and the metallization stack 1419 can be used to route I/O signals from the conductive contacts 1436 to transistors 1440 and any other components integrated into the die 1400.

Multiple integrated circuits 1400 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

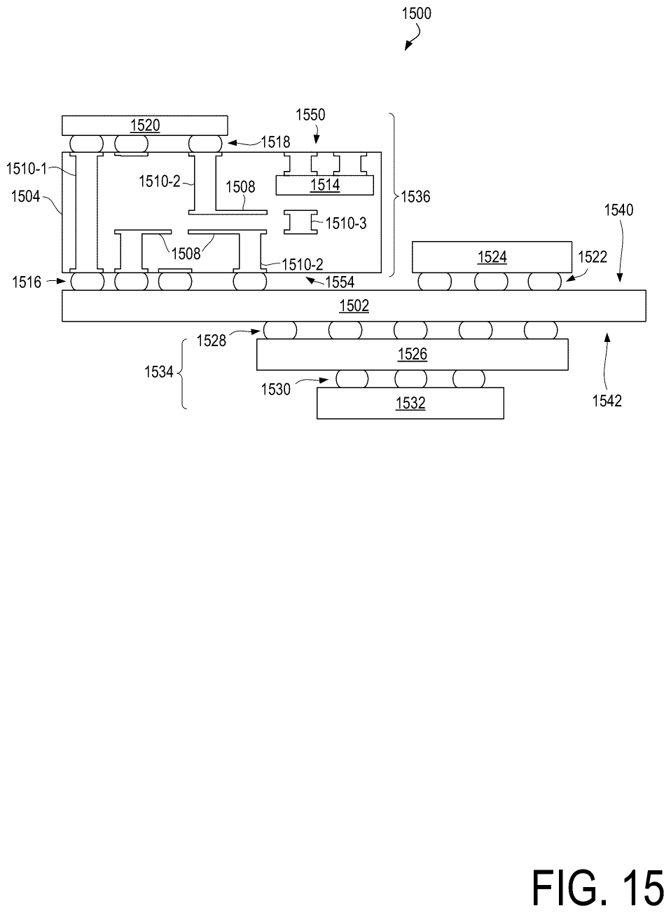

FIG. 15 is a cross-sectional side view of a microelectronic assembly 1500 that may include any of the embodiments disclosed herein. The microelectronic assembly 1500 includes multiple integrated circuit components disposed on a circuit board 1502 (which may be a motherboard, system board, mainboard, etc.). The microelectronic assembly 1500 may include components disposed on a first face 1540 of the circuit board 1502 and an opposing second face 1542 of the circuit board 1502; generally, components may be disposed on one or both faces 1540 and 1542.

In some embodiments, the circuit board 1502 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1502. In other embodiments, the circuit board 1502 may be a non-PCB substrate. The microelectronic assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502, and may include solder balls (as shown in FIG. 15), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1536 may include an integrated circuit component 1520 coupled to an interposer 1504 by coupling components 1518. The coupling components 1518 may take any suitable form for the application, such as the forms discussed above with reference to the coupling components 1516. Although a single integrated circuit component 1520 is shown in FIG. 15, multiple integrated circuit components may be coupled to the interposer 1504; indeed, additional interposers may be coupled to the interposer 1504. The interposer 1504 may provide an intervening substrate used to bridge the circuit board 1502 and the integrated circuit component 1520.

The integrated circuit component 1520 may be a packaged or unpackaged integrated circuit component that includes one or more integrated circuit dies (e.g., the die 1302 of FIG. 13, the integrated circuit 1400 of FIG. 14) and/or one or more other suitable components.

The unpackaged integrated circuit component 1520 comprises solder bumps attached to contacts on the die. The solder bumps allow the die to be directly attached to the interposer 1504. In embodiments where the integrated circuit component 1520 comprises multiple integrated circuit dies, the dies can be of the same type (a homogeneous multi-die integrated circuit component) or of two or more different types (a heterogeneous multi-die integrated circuit component). In addition to comprising one or more processor units, the integrated circuit component 1520 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1504 may spread connections to a wider pitch or reroute a connection to a different connection. For example, the interposer 1504 may couple the integrated circuit component 1520 to a set of ball grid array (BGA) conductive contacts of the coupling components 1516 for coupling to the circuit board 1502. In the embodiment illustrated in FIG. 15, the integrated circuit component 1520 and the circuit board 1502 are attached to opposing sides of the interposer 1504; in other embodiments, the integrated circuit component 1520 and the circuit board 1502 may be attached to a same side of the interposer 1504. In some embodiments, three or more components may be interconnected by way of the interposer 1504.

In some embodiments, the interposer 1504 may be formed as a PCB, including multiple metal layers separated from one another by layers of dielectric material and interconnected by electrically conductive vias. In some embodiments, the interposer 1504 may be formed of an epoxy resin, a fiberglass-reinforced epoxy resin, an epoxy resin with inorganic fillers, a ceramic material, or a polymer material such as polyimide. In some embodiments, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through hole vias 1510-1 (that extend from a first face 1550 of the interposer 1504 to a second face 1554 of the interposer 1504), blind vias 1510-2 (that extend from the first or second faces 1550 or 1554 of the interposer 1504 to an internal metal layer), and buried vias 1510-3 (that connect internal metal layers).

In some embodiments, the interposer 1504 can comprise a silicon interposer. Through-silicon vias (TSV) extending through the silicon interposer can connect connections on a first face of a silicon interposer to an opposing second face of the silicon interposer. In some embodiments, an interposer 1504 comprising a silicon interposer can further comprise one or more routing layers to route connections on a first face of the interposer 1504 to an opposing second face of the interposer 1504.

The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art. In embodiments where the interposer is a non-printed circuit board

The integrated circuit assembly 1500 may include an integrated circuit component 1524 coupled to the first face 1540 of the circuit board 1502 by coupling components 1522. The coupling components 1522 may take the form of any of the embodiments discussed above with reference to the coupling components 1516, and the integrated circuit component 1524 may take the form of any of the embodiments discussed above with reference to the integrated circuit component 1520.

The integrated circuit assembly 1500 illustrated in FIG. 15 includes a package-on-package structure 1534 coupled to the second face 1542 of the circuit board 1502 by coupling components 1528. The package-on-package structure 1534 may include an integrated circuit component 1526 and an integrated circuit component 1532 coupled together by coupling components 1530 such that the integrated circuit component 1526 is disposed between the circuit board 1502 and the integrated circuit component 1532. The coupling components 1528 and 1530 may take the form of any of the embodiments of the coupling components 1516 discussed above, and the integrated circuit components 1526 and 1532 may take the form of any of the embodiments of the integrated circuit component 1520 discussed above. The package-on-package structure 1534 may be configured in accordance with any of the package-on-package structures known in the art.

FIG. 16 is a block diagram of an example electrical device 1600 that may include one or more of the embodiments disclosed herein. For example, any suitable ones of the components of the electrical device 1600 may include one or more of the microelectronic assemblies 1500, integrated circuit components 1520, integrated circuits 1400, integrated circuit dies 1302, or structures disclosed herein. A number of components are illustrated in FIG. 16 as included in the electrical device 1600, but any one or more of these components may be omitted or duplicated, as suitable for the application. In some embodiments, some or all the components included in the electrical device 1600 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1600 may not include one or more of the components illustrated in FIG. 16, but the electrical device 1600 may include interface circuitry for coupling to the one or more components. For example, the electrical device 1600 may not include a display device 1606, but may include display device interface circuitry (e.g., a connector and driver circuitry) to which a display device 1606 may be coupled. In another set of examples, the electrical device 1600 may not include an audio input device 1624 or an audio output device 1608, but may include audio input or output device interface circuitry (e.g., connectors and supporting circuitry) to which an audio input device 1624 or audio output device 1608 may be coupled.

The electrical device 1600 may include one or more processor units 1602 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1602 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1600 may include a memory 1604, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1604 may include memory that is located on the same integrated circuit die as the processor unit 1602. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1600 can comprise one or more processor units 1602 that are heterogeneous or asymmetric to another processor unit 1602 in the electrical device 1600. There can be a variety of differences between the processor units 1602 in a system in terms of a spectrum of metrics of merit including architectural, microarchitectural, thermal, power consumption characteristics, and the like. These differences can effectively manifest themselves as asymmetry and heterogeneity among the processor units 1602 in the electrical device 1600.

In some embodiments, the electrical device 1600 may include a communication component 1612 (e.g., one or more communication components). For example, the communication component 1612 can manage wireless communications for the transfer of data to and from the electrical device 1600. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1612 may operate in accordance with other wireless protocols in other embodiments. The electrical device 1600 may include an antenna 1622 to facilitate wireless communications and/or to receive other wireless communications (such as AM or FM radio transmissions).

In some embodiments, the communication component 1612 may manage wired communications, such as electrical, optical, or any other suitable communication protocols (e.g., IEEE 802.3 Ethernet standards). As noted above, the communication component 1612 may include multiple communication components. For instance, a first communication component 1612 may be dedicated to shorter-range wireless communications such as Wi-Fi or Bluetooth, and a second communication component 1612 may be dedicated to longer-range wireless communications such as global positioning system (GPS), EDGE, GPRS, CDMA, WiMAX, LTE, EV-DO, or others. In some embodiments, a first communication component 1612 may be dedicated to wireless communications, and a second communication component 1612 may be dedicated to wired communications.

The electrical device 1600 may include battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include a display device 1606 (or corresponding interface circuitry, as discussed above). The display device 1606 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1600 may include an audio output device 1608 (or corresponding interface circuitry, as discussed above). The audio output device 1608 may include any embedded or wired or wirelessly connected external device that generates an audible indicator, such speakers, headsets, or earbuds.

The electrical device 1600 may include an audio input device 1624 (or corresponding interface circuitry, as discussed above). The audio input device 1624 may include any embedded or wired or wirelessly connected device that generates a signal representative of a sound, such as microphones, microphone arrays, or digital instruments (e.g., instruments having a musical instrument digital interface (MIDI) output). The electrical device 1600 may include a Global Navigation Satellite System (GNSS) device 1618 (or corresponding interface circuitry, as discussed above), such as a Global Positioning System (GPS) device. The GNSS device 1618 may be in communication with a satellite-based system and may determine a geolocation of the electrical device 1600 based on information received from one or more GNSS satellites, as known in the art.

The electrical device 1600 may include another output device 1610 (or corresponding interface circuitry, as discussed above). Examples of the other output device 1610 may include an audio codec, a video codec, a printer, a wired or wireless transmitter for providing information to other devices, or an additional storage device.

The electrical device 1600 may include another input device 1620 (or corresponding interface circuitry, as discussed above). Examples of the other input device 1620 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1600 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1600 may be any other electronic device that processes data. In some embodiments, the electrical device 1600 may comprise multiple discrete physical components. Given the range of devices that the electrical device 1600 can be manifested as in various embodiments, in some embodiments, the electrical device 1600 can be referred to as a computing device or a computing system.

Thus, embodiments of an improved via structure for use with the embedded component have been provided. The provided embodiments advantageously enable the use of finer pitch architectures and high-density input/output (I/O) designs in multi-chip packaging.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### Examples

Example 1 is an apparatus, including: a substrate having a front side with at least one conductive trace overlaid with a first encapsulation layer, a back side with at least one conductive pad overlaid with a second encapsulation layer, and one or more electrically conductive pathways arranged at a first line and space interval and extending from the front side to the back side; a glass layer comprising an upper surface, a lower surface, and a through-glass via (TGV) that extends from the upper surface to the lower surface; a routing material on the upper surface of the glass layer, the routing material patterned with a second line and space interval; the lower surface of the glass layer attached to the front side of the substrate; and an electrically conductive path from the routing material through the TGV to the at least one conductive trace in the substrate.

Example 2 includes the subject matter of Example 1, wherein the routing material on the upper surface of the glass layer is overlaid with a dielectric material, and the dielectric material plus the routing material is collectively referred to as a high density patterned (HDP) layer.

Example 3 includes the subject matter of Example 1 or Example 2, wherein the second line and space interval is smaller than the first line and space interval.

Example 4 includes the subject matter of any one of Examples 1-3, wherein the first encapsulation layer is thinner than the second encapsulation layer.

Example 5 includes the subject matter of any one of Examples 1-4, further comprising a bond film for attaching the lower surface of the glass layer to the front side of the substrate.

Example 6 includes the subject matter of any one of Examples 1-5, further comprising a plug comprising conductive material located in the second encapsulation layer, the plug having walls that are substantially straight and sloped, the plug substantially coaxial with the TGV and contacting the at least one conductive trace in the substrate.

Example 7 includes the subject matter of any one of Examples 1-6, wherein the glass layer comprises silicon and oxygen.

Example 8 includes the subject matter of any one of Examples 1-6, wherein the glass layer comprises silicon, oxygen, and aluminum, boron, or an alkaline-earth metal.

Example 9 includes the subject matter of any one of Examples 1-6, wherein the glass layer has a thickness in a range of about 20 microns to about 1 millimeter.

Example 10 includes the subject matter of Example any one of Examples 1-6, wherein the TGV has a diameter of about 2 microns to about 150 microns.

Example 11 includes the subject matter of Example 1, further comprising: a first one or more dielectric layers comprising redistribution layers (RDL) located on the upper surface of the glass layer; and a second one or more dielectric layers comprising redistribution layers (RDL) located on the back side of the substrate.

Example 12 includes the subject matter of Example 1, further comprising a first one or more dielectric layers comprising redistribution layers (RDL) located on the upper surface of the glass layer to complete a front side of a structure; a second one or more dielectric layers comprising redistribution layers (RDL) located on the back side of the substrate to complete a back side of the structure; a first arrangement of solder bumps on the front side of the structure; and a second arrangement of solder bumps on the back side of the structure.

Example 13 is a system on chip (SoC) comprising the subject matter of Example 12, including a first die and a second die attached to respective of the first arrangement of solder bumps.

Example 14 includes the subject matter of Example 13, further comprising a printed circuit board (PCB) and the SoC is attached, via the second arrangement of solder bumps, to the PCB.

Example 15 is an apparatus, including: an epoxy core having a front side with at least one conductive trace overlaid with a first encapsulation layer, a back side with at least one conductive pad overlaid with a second encapsulation layer, and one or more electrically conductive pathways arranged at a first line and space interval and extending from the front side to the back side; a glass layer comprising an upper surface, a lower surface, and a through-glass via (TGV) that extends from the upper surface to the lower surface; a plurality of high density patterned (HDP) layers on the upper surface of the glass layer, wherein individual of the HDP layers comprise a routing material patterned with a second line and space interval that is smaller than the first line and space interval overlaid with a dielectric material; the lower surface of the glass layer located on the front side of the epoxy core; and an electrically conductive path from an HDP layer of the plurality of HDP layers through the TGV to the at least one conductive trace on the front side of the epoxy core.

Example 16 includes the subject matter of Example 15, further comprising a plug comprising conductive material located in the second encapsulation layer, the plug having walls that are substantially straight and sloped, the plug substantially coaxial with the TGV and contacting the at least one conductive trace on the front side of the epoxy core.

Example 17 includes the subject matter of Example 15 or Example 16, further comprising, a first one or more dielectric layers comprising redistribution layers (RDL) located on the upper surface of the glass layer to complete a front side of a structure; a second one or more dielectric layers comprising redistribution layers (RDL) located on the back side of the epoxy core to complete a back side of the structure; a first arrangement of solder bumps on the front side of the structure; and a second arrangement of solder bumps on the back side of the structure.

Example 18 includes the subject matter of any one of Examples 15 to 17, further comprising: a first die and a second die attached to respective of the first arrangement of solder bumps; and a printed circuit board (PCB) attached, via the second arrangement of solder bumps.

Example 19 is a method, including: fabricating a substrate having a front side with at least one conductive trace overlaid with a first encapsulation layer, a back side with at least one conductive pad overlaid with a second encapsulation layer, and one or more electrically conductive pathways arranged at a first line and space interval and extending from the front side to the back side; forming a stitching medium comprising an upper surface, a lower surface, and a through-hole that extends from the upper surface to the lower surface; patterning the upper surface of the stitching medium with a routing material at a second line and space interval that is smaller than the first line and space interval; attaching the lower surface of the stitching medium to the front side of the substrate; depositing a resist layer on top of the upper surface of the stitching medium; dry etching the upper surface through the resist layer; and plating an electrically conductive path through the upper surface, subsequent to dry etching, the electrically conductive path extending from the routing material through the through-hole to the at least one conductive trace in the substrate.

Example 20 includes the subject matter of Example 19, further comprising: locating a first one or more dielectric layers comprising redistribution layers (RDL) on the upper surface of the stitching medium to complete a front side of a structure; and locating a second one or more dielectric layers comprising redistribution layers (RDL) on the back side of the substrate to complete a back side of the structure.

Example 21 includes the subject matter of Example 20, further comprising: locating a first arrangement of solder bumps on the front side of the structure; and locating a second arrangement of solder bumps on the back side of the structure.

Example 22 includes the subject matter of Example 21, further comprising attaching one or more die to the front side of the structure.

Example 23 includes the subject matter of Example 22, further comprising, attaching a printed circuit board to the back side of the structure.

Example 24 includes the subject matter of Example 19, further comprising depositing a seed on the upper surface and on the back side of the substrate.

Example 25 includes the subject matter of Example 22, further comprising etching a resist pattern on the back side of the substrate.

What is claimed is:

1. An apparatus, comprising:
a substrate having a front side with at least one conductive trace overlaid with a first encapsulation layer, a back side with at least one conductive pad overlaid with a second encapsulation layer, and one or more electrically conductive pathways arranged at a first line and space interval and extending from the front side to the back side;
a glass layer comprising an upper surface, a lower surface, and a through-glass via (TGV) that extends from the upper surface to the lower surface;
a routing material on the upper surface of the glass layer, the routing material patterned with a second line and space interval;
the lower surface of the glass layer attached to the front side of the substrate; and
an electrically conductive path from the routing material through the TGV to the at least one conductive trace in the substrate.

2. The apparatus of claim 1, wherein the routing material on the upper surface of the glass layer is overlaid with a dielectric material, and the dielectric material plus the routing material is collectively referred to as a high density patterned (HDP) layer.

3. The apparatus of claim 1, wherein the second line and space interval are smaller than the first line and space interval.

4. The apparatus of claim 1, wherein the first encapsulation layer is thinner than the second encapsulation layer.

5. The apparatus of claim 1, further comprising a bond film for attaching the lower surface of the glass layer to the front side of the substrate.

6. The apparatus of claim 1, further comprising a plug comprising conductive material located in the second encapsulation layer, the plug having walls that are substantially straight and sloped, the plug substantially coaxial with the TGV and contacting the at least one conductive trace in the substrate.

7. The apparatus of claim 1, wherein the glass layer comprises silicon and oxygen.

8. The apparatus of claim 1, wherein the glass layer comprises silicon, oxygen, and aluminum, boron, or an alkaline-earth metal.

9. The apparatus of claim 1, wherein the glass layer has a thickness in a range of about 20 microns to about 1 millimeter.

10. The apparatus of claim 1, wherein the TGV has a diameter of about 2 microns to about 150 microns.

11. The apparatus of claim 1, further comprising:
a first one or more dielectric layers comprising redistribution layers (RDL) located on the upper surface of the glass layer; and
a second one or more dielectric layers comprising redistribution layers (RDL) located on the back side of the substrate.

12. The apparatus of claim 1, further comprising:
a first one or more dielectric layers comprising redistribution layers (RDL) located on the upper surface of the glass layer to complete a front side of a structure;
a second one or more dielectric layers comprising redistribution layers (RDL) located on the back side of the substrate to complete a back side of the structure;
a first arrangement of solder bumps on the front side of the structure; and
a second arrangement of solder bumps on the back side of the structure.

13. A system on chip (SoC) comprising:
the apparatus of claim 12, including a first die and a second die attached to respective of the first arrangement of solder bumps.

14. The SoC of claim 13, further comprising a printed circuit board (PCB) and the SoC is attached, via the second arrangement of solder bumps, to the PCB.

15. An apparatus, comprising:
an epoxy core having a front side with at least one conductive trace overlaid with a first encapsulation layer, a back side with at least one conductive pad overlaid with a second encapsulation layer, and one or more electrically conductive pathways arranged at a first line and space interval and extending from the front side to the back side;
a glass layer comprising an upper surface, a lower surface, and a through-glass via (TGV) that extends from the upper surface to the lower surface;
a plurality of high density patterned (HDP) layers on the upper surface of the glass layer, wherein individual of the HDP layers comprise a routing material patterned with a second line and space interval that is smaller than the first line and space interval overlaid with a dielectric material;
the lower surface of the glass layer located on the front side of the epoxy core; and
an electrically conductive path from an HDP layer of the plurality of HDP layers through the TGV to the at least one conductive trace on the front side of the epoxy core.

16. The apparatus of claim 15, further comprising a plug comprising conductive material located in the second encapsulation layer, the plug having walls that are substantially straight and sloped, the plug substantially coaxial with the TGV and contacting the at least one conductive trace on the front side of the epoxy core.

17. The apparatus of claim 15 further comprising,
a first one or more dielectric layers comprising redistribution layers (RDL) located on the upper surface of the glass layer to complete a front side of a structure;
a second one or more dielectric layers comprising redistribution layers (RDL) located on the back side of the epoxy core to complete a back side of the structure;
a first arrangement of solder bumps on the front side of the structure; and
a second arrangement of solder bumps on the back side of the structure.

18. The apparatus of claim 17, further comprising:
a first die and a second die attached to respective of the first arrangement of solder bumps; and
a printed circuit board (PCB) attached via the second arrangement of solder bumps.

19. A method, comprising:
fabricating a substrate having a front side with at least one conductive trace overlaid with a first encapsulation layer, a back side with at least one conductive pad overlaid with a second encapsulation layer, and one or more electrically conductive pathways arranged at a first line and space interval and extending from the front side to the back side;
forming a stitching medium comprising an upper surface, a lower surface, and a through-hole that extends from the upper surface to the lower surface;
patterning the upper surface of the stitching medium with a routing material at a second line and space interval that is smaller than the first line and space interval;
attaching the lower surface of the stitching medium to the front side of the substrate;
depositing a resist layer on top of the upper surface of the stitching medium;
dry etching the upper surface through the resist layer; and
plating an electrically conductive path through the upper surface, subsequent to dry etching, the electrically conductive path extending from the routing material through the through-hole to the at least one conductive trace in the substrate.

20. The method of claim 19, further comprising:
locating a first one or more dielectric layers comprising redistribution layers (RDL) on the upper surface of the stitching medium to complete a front side of a structure; and
locating a second one or more dielectric layers comprising redistribution layers (RDL) on the back side of the substrate to complete a back side of the structure.

21. The method of claim 20, further comprising:
locating a first arrangement of solder bumps on the front side of the structure; and
locating a second arrangement of solder bumps on the back side of the structure.

22. The method of claim 21, further comprising attaching one or more die to the front side of the structure.

23. The method of claim 22, further comprising, attaching a printed circuit board to the back side of the structure.

24. The method of claim 19, further comprising depositing a seed on the upper surface and on the back side of the substrate.

25. The method of claim 22, further comprising etching a resist pattern on the back side of the substrate.
